(19) United States
(12) Patent Application Publication
(10) Pub. No.: US 2010/0103225 A1
(43) Pub. Date: Apr. 29, 2010

(54) INKJET HEAD

(75) Inventors: Boum-Seock Kim, Suwon-si (KR); Jae-Woo Joung, Suwon-si (KR); Jae-Hun Kim, Seoul (KR); Young-Seuck Yoo, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/469,774

(22) Filed: May 21, 2009

(30) Foreign Application Priority Data
Oct. 29, 2008 (KR) 10-2008-0106427

(51) Int. Cl. B41J 2/045; H01L 41/16

(52) U.S. Cl. 347/68; 310/311

(57) ABSTRACT

An inkjet head is disclosed. The inkjet head can include a nozzle, configured to discharge ink; a chamber, configured to supply the ink to the nozzle; and a piezoelectric element, configured to receive electricity from an external power source and press the chamber, being made of a material having xPb(Mg_{1/3}Nb_{2/3})O₃-yPbZrO₃-zPbTiO₃ (x+y+z=1, 0<x<1, 0<y<1, 0<z<1), and having a single crystal structure. According to an embodiment of the present invention, it is possible to increase an ink discharging speed and significantly reduce an actuating voltage for the piezoelectric element by significantly the piezoelectric property. Moreover, the processing temperature and ink temperature can be prevented from being limited by the piezoelectric element when the ink is discharged.

### CROSS-REFERENCE TO RELATED APPLICATIONS

This application claims the benefit of Korean Patent Application No. 10-2008-0106427, filed with the Korean Intellectual Property Office on Oct. 29, 2008, the disclosure of which is incorporated herein by reference in its entirety.

### BACKGROUND

1. Technical Field

The present invention relates to an inkjet head.

2. Description of the Related Art

An inkjet head converts an electric signal to a physical force to discharge an ink droplet.

The inkjet head includes a reservoir, a restrictor, a chamber, a nozzle, and a piezoelectric element. Each of the elements can be individually processed on various layers, and then the layers can be coupled to one another, in order to manufacture the inkjet head.

FIG. 1 is an enlarged view showing a crystalline structure of a piezoelectric element 10 of the conventional inkjet head. Referring to FIG. 1, the piezoelectric element 10 of the conventional inkjet head is made of a material having a polycrystalline structure such as PZT.

In accordance with the conventional art, however, the piezoelectric element has the polycrystalline structure, thereby allowing the low piezoelectricity to be generated by using the supplied electricity. Accordingly, the actuating voltage for actuating the piezoelectric element should be increased.

### SUMMARY

The present invention provides an inkjet head including a piezoelectric element having improved piezoelectric properties.

An aspect of present invention features an inkjet head including a nozzle, configured to discharge ink; a chamber, configured to supply the ink to the nozzle; and a piezoelectric element, configured to receive electricity from an external power source and press the chamber, being made of a material having xPb(Mg_{1/3}Nb_{2/3})O₃-yPbZrO₃-zPbTiO₃ (x+y+z=1, 0<x<1, 0<y<1, 0<z<1), and having a single crystalline structure.

At this time, the piezoelectric element can be made of a material further having MnO₂.

The MnO₂ content can be 0.1 weight percent in the piezoelectric element.

In the xPb(Mg_{1/3}Nb_{2/3})O₃-yPbZrO₃-zPbTiO₃, x, y, and z can have 0.1 to 0.4, 0.25 to 0.5, and 0.35 to 0.4, respectively.

In the xPb(Mg_{1/3}Nb_{2/3})O₃-yPbZrO₃-zPbTiO₃, x, y, and z can have 0.4, 0.25, and 0.35, respectively.

### BRIEF DESCRIPTION OF THE DRAWINGS

FIG. 1 is an enlarged view showing a crystalline structure of a piezoelectric element of the conventional inkjet head;

FIG. 2 is a cross-sectional view showing an inkjet head in accordance with an embodiment of the present invention; and

FIG. 3 is an enlarged view showing a crystalline structure of a piezoelectric element of an inkjet head in accordance with an embodiment of the present invention.

### DETAIL DESCRIPTION

An inkjet head according to an embodiment of the present invention will be described in detail with reference to the accompanying drawings. Identical or corresponding elements will be given the same reference numerals, regardless of the figure number, and any redundant description of the identical or corresponding elements will not be repeated

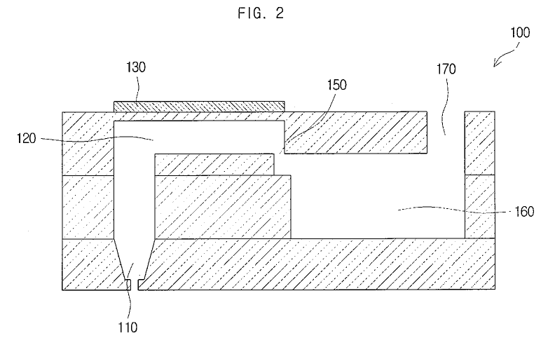

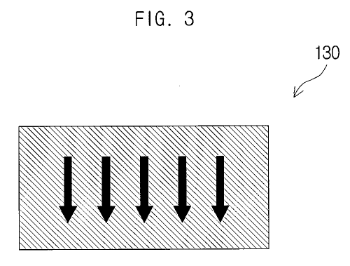

FIG. 2 is a cross-sectional view showing an inkjet head 100 in accordance with an embodiment of the present invention, and FIG. 3 is an enlarged view showing a crystalline structure of a piezoelectric element 130 of the inkjet head 100.

In accordance with an embodiment of the present invention as shown in FIG. 2 and FIG. 3, the inkjet head 100 can include: a nozzle 110, discharging ink; a chamber 120, supplying the ink to the nozzle 110; and a piezoelectric element 130, receiving electricity from an external power source to press the chamber 120 and being made of a material having xPb(Mg_{1/3}Nb_{2/3})O₃-yPbZrO₃-zPbTiO₃ (x+y+z=1, 0<x<1, 0<y<1, 0<z<1) to having a single crystalline structure.

In accordance with an embodiment of the present invention, it is possible to significantly improve a piezoelectric property by using the piezoelectric element 130 that is made of the single crystalline xPb(Mg_{1/3}Nb_{2/3})O₃-yPbZrO₃-zPbTiO₃ (x+y+z=1, 0<x<1, 0<y<1, 0<z<1), thereby increasing an ink discharging speed and significantly reducing an actuating voltage for actuating the piezoelectric element 130, as compared with the conventional piezoelectric element having a polycrystalline structure.

Due to high curie temperature T_{C}, at which the phase transition of a material is started, and high rhombohedral to tetragonal temperature T_{RT}, the single crystalline xPb(Mg_{1/3}Nb_{2/3})O₃-yPbZrO₃-zPbTiO₃ (x+y+z=1, 0<x<1, 0<y<1, 0<z<1) is little affected by the surrounding temperature. Accordingly, the processing temperature and ink temperature can be prevented from being limited by the piezoelectric element 130 when ink is discharged.

Hereinafter, each element will be described in more detail with reference to FIG. 2 and FIG. 3.

As shown in FIG. 2, the inkjet head 100 can include an inlet 170, a reservoir 160, a restrictor 150, a chamber 120, a piezoelectric element 130, and a nozzle 110. In the case of the inlet 170, the reservoir 160, the restrictor 150, the chamber 120, and the nozzle 110, each of the elements can be formed by being individually processed on a plurality of boards and then the boards can be coupled to one another.

The reservoir 160 can receive ink through the inlet 170 to contain the ink and supply the ink to the chamber 120 through the restrictor 150, which will be described below.

The restrictor 150 can function as a path that connects the reservoir 160 and the chamber 120, which will be described below, to supply the ink from the reservoir 160 to the chamber 120. The restrictor 150 can have a cross-section that is smaller than that of the reservoir 160. The restrictor 150 can also adjust the amount of ink supplied from the reservoir 160 to the chamber 120 if the chamber 120 is pressed by the piezoelectric element 130.

The chamber 120 can have one side that is coupled to the restrictor 150 to be connected to the reservoir 160 and the other side that is coupled to the nozzle 110. Accordingly, the chamber 120 can receive ink from the reservoir 160 and supply the ink to the nozzle 110 in order to perform the printing.

The nozzle 110 can be connected to the chamber 120 and receive ink from the chamber 120 to discharge the ink. If the chamber 120 is pressed by the vibration, which has been generated by the piezoelectric element 130, which will be described below, and transferred to the chamber 120, this pressure can allow the nozzle 110 to discharge the ink.

The piezoelectric element 130 can be placed above the chamber 120 and receive electricity from an external power source to generate vibration. That is, the piezoelectric element 130 can press the chamber 120 through a vibration plate by generating vibration according to the supplied voltage. In this case, an electrode (not shown) can be formed on a surface of the piezoelectric element 130 to supply electricity from an external power source to the piezoelectric element 130.

The piezoelectric element 130 can be made of a material having xPb(Mg_{1/3}Nb_{2/3})O₃-yPbZrO₃-zPbTiO₃ (x+y+z=1, 0<x<1, 0<y<1, 0<z<1) to have a single crystalline structure. Here, x, y, and z, which are mol ratios, refer to component ratios between Pb(Mg_{1/3}Nb_{2/3})O₃, PbZrO₃, and PbTiO₃.

As shown in FIG. 3, it is possible to significantly improve a piezoelectric property by allowing the piezoelectric element 130 to be made of the single crystalline xPb(Mg_{1/3}Nb_{2/3})O₃-yPbZrO₃-zPbTiO₃ (x+y+z=1, 0<x<1, 0<y<1, 0<z<1), thereby increasing an ink discharging speed and significantly reducing an actuating voltage for the piezoelectric element 130, as compared with the conventional piezoelectric element having a polycrystalline structure.

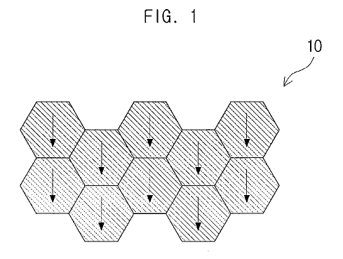

The difference in the piezoelectric effect between the conventional art and the embodiment of the present invention are represented as arrows in the crystalline structure shown in FIG. 1 and FIG. 3. In particular, while the piezoelectric effect generated in each unit crystal is scattered in the conventional piezoelectric element having polycrystalline structure as shown in FIG. 1, the piezoelectric effect of one crystal can be gathered in the piezoelectric element 130 having the single structure as shown in FIG. 3, thereby resulting in improvement of the whole piezoelectric effect.

Due to high curie temperature T_{C}, at which the phase transition of a material is started, and high rhombohedral to tetragonal temperature T_{RT}, the single crystalline xPb(Mg_{1/3}Nb₂₃)O₃-yPbZrO₃-zPbTiO₃ (x+y+z=1, 0<x<1, 0<y<1, 0<z<1) is little affected by the surrounding temperature. Accordingly, the processing temperature and ink temperature can be prevented from being limited by the piezoelectric element 130 when ink is discharged.

Hereinafter, the piezoelectric element 130 made of the single crystalline xPb(Mg_{1/3}Nb_{2/3})O₃-yPbZrO₃-zPbTiO₃ (x+y+z=1, 0<x<1, 0<y<1, 0<z<1) will be described again with reference to the following table 1, in which the curie temperature T_{C} and the rhombohedral to tetragonal temperature T_{RT} of a polycrystalline PZT(PbZrₐTi₁₋ₐO₃), a single crystalline PMN-PT{bPb(Mg_{1/3}Nb_{2/3})O₃-cPbTiO₃(b+c=1, 0<b<1, 0<c<1)} and a single crystalline PMN-PZT{xPb(Mg_{1/3}Nb_{2/3})O₃-yPbZrO₃-zPbTiO₃ (x+y+z=1, 0<x<1, 0<y<1, 0<z<1)} are compared.

TABLE 1

| | T_{C} (° C.) | T_{RT} (° C.) | d₃₂ (pC/N) |
|---|---|---|---|
| Polycrystalline PZT | 190 | — | −275 |
| Single crystalline PMN-PT | 130 | 98 | −1350 |
| Single crystalline PMN- | 205 | 165 | −850 |
| PZT | | | |

As shown in the table 1, it can be recognized that the widthwise piezoelectric coefficient d₃₂ on the basis of FIG. 2 in the piezoelectric element 130 made of the single crystalline PMN-PZT has −850 pC/N(picoCoulomb/Newton), which is a significantly increased value as compared with the piezoelectric element having the polycrystalline structure, such as the polycrystalline PZT.

In accordance with an embodiment of the present invention, it is possible to significantly improve a piezoelectric property by using the piezoelectric element 130 made of the single crystalline xPb(Mg_{1/3}Nb_{2/3})O₃-yPbZrO₃-zPbTiO₃ (x+y+z=1, 0<x<1, 0<y<1, 0<z<1) to significantly increase the value d₃₂ as compared with the piezoelectric element having the polycrystalline structure, thereby increasing the displacement for pressing the chamber 120 to efficiently change the volume of the chamber 120. Accordingly, an ink discharging speed can be increased and an actuating voltage for the piezoelectric element 130 can be significantly reduced.

As shown in the above table 1, it can be recognized that the values Tc and T_{RT} in the piezoelectric element made of the single crystalline PMN-PZT have 205° C. and 165° C., respectively, which are significantly increased values as compared with the single crystalline PMN-PT.

In accordance with an embodiment of the present invention, it is possible to prevent the processing temperature and ink temperature from being limited by the piezoelectric element 130 when the ink is discharged, by allowing the piezoelectric element 130 to be made of the single crystalline xPb(Mg_{1/3}Nb_{2/3})O₃-yPbZrO₃-zPbTiO₃ (x+y+z=1, 0<x<1, 0<y<1, 0<z<1) to significantly increase the values Tc and T_{RT}.

The single crystalline xPb(Mg_{1/3}Nb_{2/3})O₃-yPbZrO₃-zPbTiO₃ (x+y+z=1, 0<x<1, 0<y<1, 0<z<1) can be made by, for example, the solid-state single crystalline growth. In particular, a seed single crystal made of the single crystalline xPb(Mg_{1/3}Nb_{2/3})O₃-yPbZrO₃-zPbTiO₃ (x+y+z=1, 0<x<1, 0<y<1, 0<z<1) can be coupled to a poly-crystalloid, and then the heat-treatment can be performed for the seed single crystal and the poly-crystalloid to grow the seed single crystal into the poly-crystalloid, to thereby make the piezoelectric element 130 made of the single crystalline xPb(Mg_{1/3}Nb_{2/3})O₃-yPbZrO₃-zPbTiO₃ (x+y+z=1, 0<x<1, 0<y<1, 0<z<1).

On the other hand, the piezoelectric element 130 can be made by further adding MnO₂ in addition to the above-described xPb(Mg_{1/3}Nb_{2/3})O₃-yPbZrO₃-zPbTiO₃ (x+y+z=1, 0<x<1, 0<y<1, 0<z<1). The MnO₂ content may be 0.1 weight percent of the whole electric element 130.

In the piezoelectric element 130 made of the single crystalline xPb(Mg_{1/3}Nb_{2/3})O₃-yPbZrO₃-zPbTiO₃, x, y, and z may be 0.1 to 0.4, 0.25 to 0.5, 0.35 to 0.4, prespectively. More particularly, x, y, and z may be 0.4, 0.25, 0.35, respectively, in the piezoelectric element 130 made of the single crystalline xPb(Mg_{1/3}Nb_{2/3})O₃-yPbZrO₃-zPbTiO₃.

Hitherto, although a certain embodiment of the present invention has been shown and described for the above-described objects, it will be appreciated by any person of ordinary skill in the art that a large number of modifications, permutations and additions are possible within the principles and spirit of the invention, the scope of which shall be defined by the appended claims and their equivalents.

What is claimed is:

1. An inkjet head comprising:
a nozzle, configured to discharge ink;
a chamber, configured to supply the ink to the nozzle; and
a piezoelectric element, configured to receive electricity from an external power source and press the chamber, being made of a material having xPb(Mg_{1/3}Nb_{2/3})O₃-yPbZrO₃-zPbTiO₃ (x+y+z=1, 0<x<1, 0<y<1, 0<z<1), and having a single crystalline structure.

2. The inkjet head of claim 1, wherein the piezoelectric element is made of a material further having MnO₂.

3. The inkjet head of claim 2, wherein the MnO₂ content is 0.1 weight percent in the piezoelectric element.

4. The inkjet head of claim 1, wherein, in the xPb(Mg_{1/3}Nb_{2/3})O₃-yPbZrO₃-zPbTiO₃, x, y, and z have 0.1 to 0.4, 0.25 to 0.5, and 0.35 to 0.4, respectively.

5. The inkjet head of claim 4, wherein, in the xPb(Mg_{1/3}Nb_{2/3})O₃-yPbZrO₃-zPbTiO₃, x, y, and z have 0.4, 0.25, and 0.35, respectively.
